(19) United States
(12) Patent Application Publication
(10) Pub. No.: US 2020/0166801 A1
(43) Pub. Date: May 28, 2020

(54) LIQUID CRYSTAL DISPLAY DEVICE

(71) Applicant: HUIZHOU CHINA STAR OPTOELECTRONICS TECHNOLOGY CO., LTD., Huizhou Guangdong (CN)

(72) Inventors: Yongyuan QIU, Huizhou Guangdong (CN); Yuchun HSIAO, Huizhou Guangdong (CN)

(21) Appl. No.: 16/087,929

(22) PCT Filed: Sep. 7, 2018
(86) PCT No.: PCT/CN2018/104496

§ 371 Date: Sep. 24, 2018

(30) Foreign Application Priority Data
Apr. 19, 2018 (CN) 201810356582.5

(51) Int. Cl. G02F 1/13357; G02F 1/1335; F21V 8/00; H01L 27/32

(52) U.S. Cl. CPC G02F 1/133603; G02F 1/133514; H01L 27/3232; G02B 6/0078; G02F 1/133528; G02F 1/133606

(57) ABSTRACT

The invention provides an LCD device. The LCD device integrates the LCD panel and the backlight module, and directly disposes the backlights of the backlight module on TFT array substrate of the LCD panel, so that the backlights are disposed on the top surface of the TFT array substrate. The base substrate of the CF substrate serves as a light-guiding plate or a separate light-guiding plate to guide the light emitted by the backlights, or the backlights are disposed on the bottom surface of the TFT array substrate and uses a separate the light-guiding plate to guide the light emitted by the backlights. The TFT array substrate is provided with terminals corresponding to the pins of the backlights and wires connected to the terminals, so that the backlights can be driven by a circuit board connected to the wires to reduce the thickness, reduce cost and improve quality.

### BACKGROUND OF THE INVENTION

### 1. Field of the Invention

The present invention relates to the field of display and, in particular, to the field of liquid crystal display (LCD) device.

### 2. The Related Arts

In the field of display technology, flat panel display devices, such as liquid crystal display (LCD) device, have gradually replaced cathode ray tube (CRT) displays. The LCD device has many advantages, such as thinness, power saving, and radiation-free, and has been widely used.

Most of the LCD devices in the current market are backlight type LCDs, which comprise an LCD panel and a backlight module. In general, the LCD panel comprises a color filter (CF) substrate, a thin film transistor (TFT) array substrate, a liquid crystal (LC) layer sandwiched between the CF substrate and the TFT array substrate and a sealant. The operation principle of the LCD panel is to place LC molecules in two parallel glass substrates. A plurality of vertical and horizontal fine wires is disposed between two glass substrates, and the orientation of LC molecules controlled by the electric field generated by the current flowing through wires will refract the light from the backlight module to produces an image.

Because the LCD panel does not emit light, a light source provided by the backlight module is needed to display the image normally. Therefore, the backlight module is one of the key components of the LCD devices. The backlight module is divided into two types of edge-lit type backlight modules and direct-lit type backlight modules according to the position of the light source. The direct-lit type backlight module disposes a light source, such as a light-emitting diode (LED), behind the LCD panel and forms a planar light source directly to the LCD panel. The edge-lit type backlight module disposes a backlight LED light bar at the edge of a backplate behind the LCD panel, and the light from the LED light bar enters the light guide plate (LGP) from the light incident side of the LGP and emits from the light-exiting side of the LGP after reflection and diffusion, and then is supplied through an optical film set to form a planar light source to the LCD panel.

In the known LCD devices, either using a direct-lit type backlight module or an edge-lit type backlight module, the backlight module is disposed independently of the LCD panel. Therefore, a certain space needs to be reserved for the backlight module in the design process, so that the LCD device needs to have a certain thickness. With the ongoing development of display technologies, the thin display devices are increasingly favored by consumers. The conventional LCD devices can no longer meet the demands from the consumers for thin display devices.

### SUMMARY OF THE INVENTION

The primary object of the present invention is to provide an LCD device, thin, low cost and high quality.

To achieve the above objects, the present invention provides an LCD device, which comprises: an TFT array substrate, a CF substrate disposed on the TFT array substrate, an LC layer sandwiched between the TFT array substrate and the CF substrate, and two backlight sets disposed on the TFT array substrate; both the two backlight sets being disposed at top surface of the TFT array substrate or bottom surface of the TFT array substrate;

the TFT array substrate being disposed with a first region, a second region, and a third region successively, wherein the second region corresponds to the CF substrate; one of two backlight sets is disposed in the first region, and the other set is disposed in the third region; each backlight of the backlight set has a light-exiting surface, the light-exiting surface of each backlight being located on a side near the second region.

According to a preferred embodiment of the present invention, the two backlight sets are disposed at the top surface of the TFT array substrate;

the CF substrate comprises a base substrate having two sides respectively corresponding to boundary between the first region and the second region and boundary between the second region and the third region; the light-exiting surfaces of the backlight set located in the first region are all opposite to the side of the base substrate corresponding to the boundary between the first region and the second region, and the light-exiting surfaces of the backlight set located in the third region are all opposite to the side of the base substrate corresponding to the boundary between the second region and the third region;

the base substrate is made of a light-conductive material.

According to a preferred embodiment of the present invention, the LCD device further comprises an upper polarizer disposed between the CF substrate and the LC layer, and a lower polarizer disposed on a bottom surface of the TFT array substrate.

According to a preferred embodiment of the present invention, the two backlight sets are disposed at the bottom surface of the TFT array substrate;

the LCD device further comprises a light-guiding plate disposed under the TFT array substrate, a reflection sheet disposed on a bottom surface of the light-guiding plate, and an optical film set disposed between the TFT array substrate and the light-guiding plate;

the light-guiding plate has two opposite light incident surfaces; the light-exiting surfaces of the backlight set located in the first region are all opposite to one of the two light incident surfaces of the light-guiding plate, and the light-exiting surfaces of the backlight set located in the third region are all opposite to the other of the two light incident surfaces of the light-guiding plate.

According to a preferred embodiment of the present invention, the LCD device further comprises an upper polarizer disposed on a top surface of the CF substrate, and a lower polarizer disposed between the TFT array substrate and the optical film set.

According to a preferred embodiment of the present invention, the two backlight sets are disposed at the top surface of the TFT array substrate;

the LCD device further comprises a light-guiding plate disposed on top of the CF substrate, a reflection sheet disposed on a top surface of the light-guiding plate, and an optical film set disposed between the CF substrate and the light-guiding plate;

the light-guiding plate has two opposite light incident surfaces; the light-exiting surfaces of the backlight set located in the first region are all opposite to one of the two light incident surfaces of the light-guiding plate, and the light-exiting surfaces of the backlight set located in the third region are all opposite to the other of the two light incident surfaces of the light-guiding plate.

According to a preferred embodiment of the present invention, the LCD device further comprises an upper polarizer disposed between the CF substrate and the optical film set, and a lower polarizer disposed at the bottom surface of the TFT array substrate.

According to a preferred embodiment of the present invention, the backlight set located in the first region is arranged in a row in an arrangement parallel to the boundary between the first region and the second region;

the backlight set located in the third region is arranged in a row in an arrangement parallel to the boundary between the second region and the third region;

each backlight of the backlight set is an OLED light source.

According to a preferred embodiment of the present invention, one of the top surface and the bottom surface of the TFT array substrate disposed with the backlight sets is disposed with a terminal set corresponding to each backlight set respectively; the terminal set comprises a first terminal and a second terminal, spaced apart; each backlight has a first pin and a second pin on bottom surface, the first pin and the second pin of each backlight are respectively electrically connected to the first terminal and the second terminal of the corresponding terminal set;

one of the top surface and the bottom surface of the TFT array substrate disposed with the backlight sets is disposed with a first wire and a second wire, spaced apart, the first terminal of each terminal set is connected with the first wire, and the second terminal of each terminal set is connected with the second wire;

the TFT array substrate further comprises a fourth region connected to the first region, the second region, and the third region; the LCD device further comprises a circuit board bonded on the fourth region of the TFT array substrate, and both the first wire and the second wire are electrically connected to the circuit board.

According to a preferred embodiment of the present invention, each backlight is fixed on the TFT array substrate through an anisotropic conductive film, so that the first pin and the second pin of the backlight are respectively electrically connected to the first terminal and the second terminal of the corresponding terminal set.

The present invention provides the following advantages: the LCD device provided by the present invention integrates the structure of the LCD panel and the backlight module, and directly disposes the backlights of the backlight module on the TFT array substrate of the LCD panel, so that the backlights are disposed on the top surface of the TFT array substrate. The base substrate of the CF substrate is used as a light-guiding plate or a separate light-guiding plate is used to guide the light emitted by the backlights, or the backlights are disposed on the bottom surface of the TFT array substrate and uses a separate the light-guiding plate to guide the light emitted by the backlights. The TFT array substrate is further provided with terminals corresponding to the pins of the backlights and wires connected to the terminals, so that the backlights can be driven by a circuit board connected to the wires to effectively reduce the thickness of the LCD device, reduce product cost and improve product quality.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort.

FIG. 1 is a schematic top view showing the structure of a first embodiment of the LCD device of the present invention.

FIG. 2 is a schematic bottom view showing the structure of the first embodiment of the LCD device of the present invention.

FIG. 3 is a schematic cross-sectional view along A-A′ direction in FIG. 1.

FIG. 4 is a schematic cross-sectional view along B-B′ direction in FIG. 1.

FIG. 5 is a schematic top view showing the structure of a second embodiment of the LCD device of the present invention,

FIG. 6 is a schematic bottom view showing the structure of the second embodiment of the LCD device of the present invention.

FIG. 7 is a schematic cross-sectional view along C-C′ direction in FIG. 5.

FIG. 8 is a schematic cross-sectional view along D-D′ direction in FIG. 5.

FIG. 9 is a schematic top view showing the structure of a third embodiment of the LCD device of the present invention.

FIG. 10 is a schematic cross-sectional view along E-E′ direction in FIG. 9.

FIG. 11 is a schematic cross-sectional view along F-F′ direction in FIG. 9.

### DETAILED DESCRIPTION OF THE PREFERRED EMBODIMENTS

To further explain the technical means and effect of the present invention, the following refers to embodiments and drawings for detailed description. Apparently, the described embodiments are merely some embodiments of the present invention, instead of all embodiments. All other embodiments based on embodiments in the present invention and obtained by those skilled in the art without departing from the creative work of the present invention are within the scope of the present invention.

The terms “comprising” and “having” and any variations thereof appearing in the specification, claims, and drawings of the present application are intended to cover non-exclusive inclusion. For example, a process, method, system, product, or device that includes a series of steps or units is not limited to the listed steps or units, but optionally also includes steps or units not listed, or alternatively, other steps or units inherent to these processes, methods, products or equipment. In addition, the terms “first”, “second” and “third” are used to distinguish different objects and not intended to describe a particular order.

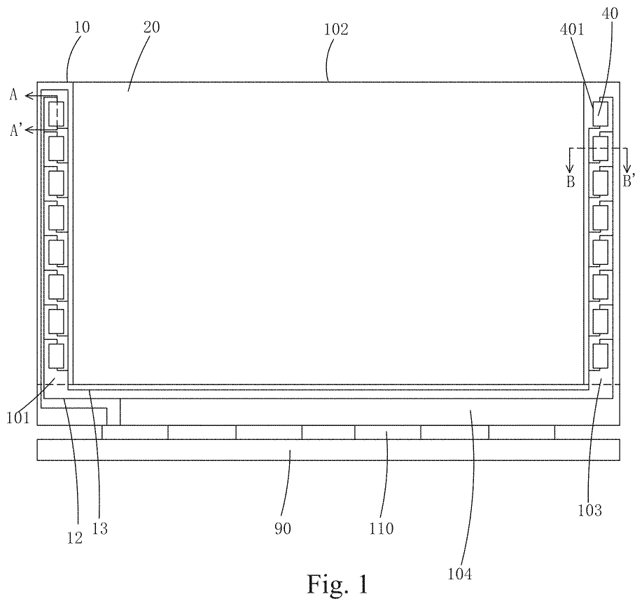

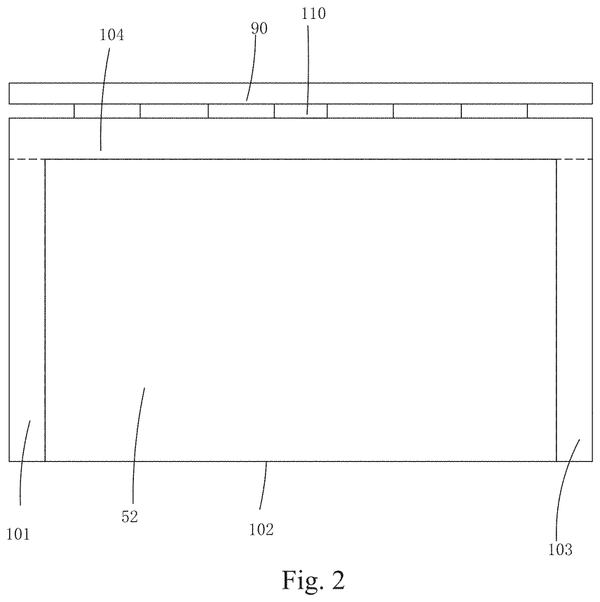

Refer to FIG. 1 to FIG. 4. The first embodiment of the LCD device provided by the present invention comprises: an TFT array substrate 10, a CF substrate 20 disposed on the TFT array substrate 10, an LC layer 30 sandwiched between the TFT array substrate 10 and the CF substrate 20, and two backlight sets 40 disposed on the TFT array substrate 10. Both the two backlight sets 40 are disposed at top surface of the TFT array substrate 10.

The TFT array substrate is disposed with a first region 101, a second region 102, and a third region 103 successively, and the second region 102 corresponds to the CF substrate 20. One of two backlight sets 40 is disposed in the first region 101, and the other set is disposed in the third region 103. Each backlight of the backlight set has a light-exiting surface 401, and the light-exiting surface 401 of each backlight is located on a side near the second region 102.

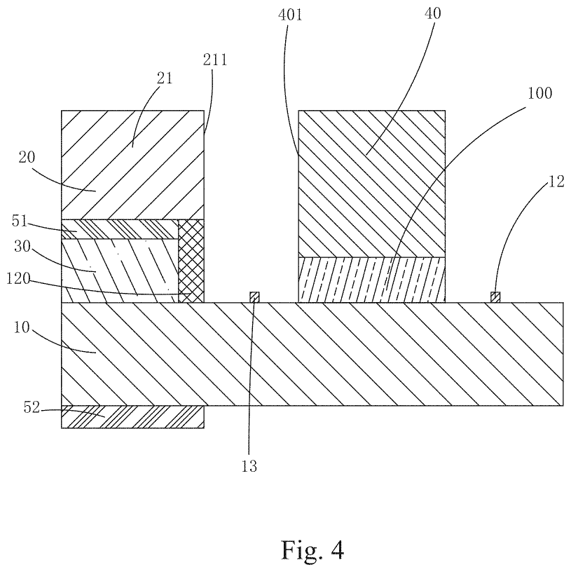

Refer to FIG. 4. The CF substrate 20 comprises a base substrate 21, and a CF layer (not shown) and a common electrode layer (not shown) disposed at the bottom of the base substrate. The base substrate 21 has two sides 211 respectively corresponding to boundary between the first region 101 and the second region 102 and boundary between the second region 102 and the third region 103. The light-exiting surfaces 41 of the backlight set 40 located in the first region 101 are all opposite to the side 211 of the base substrate 21 corresponding to the boundary between the first region 101 and the second region 102, and the light-exiting surfaces 401 of the backlight set 40 located in the third region 103 are all opposite to the side 211 of the base substrate 21 corresponding to the boundary between the second region 102 and the third region 103. The base substrate 21 is made of a light-conductive material.

Specifically, refer to FIG. 4. The LCD device further comprises a frame 120 disposed between the TFT array substrate 10 and the CF substrate 20 and located outside the LC layer 30.

Specifically, refer to FIG. 4. In the first embodiment of the present invention. The LCD device further comprises an upper polarizer 51 disposed between the CF substrate 20 and the LC layer 30, and a lower polarizer 52 disposed on a bottom surface of the TFT array substrate 10.

Specifically, refer to FIG. 1. The backlights of the backlight set 40 located in the first region 101 are arranged in a row in an arrangement direction parallel to the boundary between the first region 101 and the second region 102. The backlights of the backlight set 40 located in the third region 103 are arranged in a row in an arrangement direction parallel to the boundary between the second region 102 and the third region 103.

Specifically, each backlight of the backlight set 40 is an OLED light source.

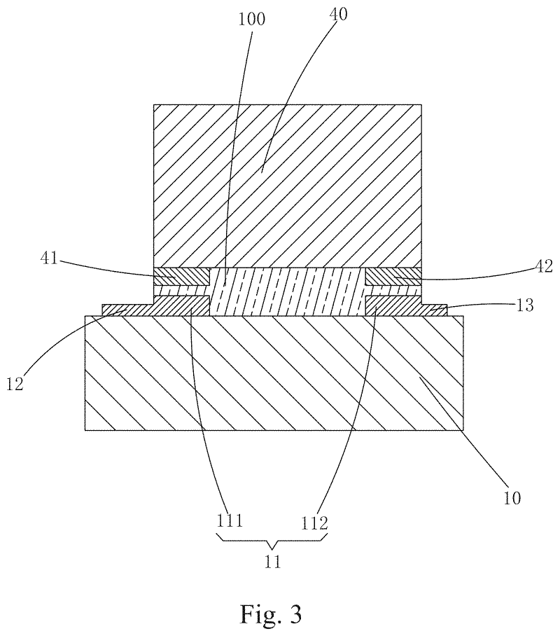

Specifically, as shown in FIG. 3, in the first embodiment of the present invention, the top surface of the TFT array substrate 10 is disposed with a terminal set 11 corresponding to each backlight set 40 respectively; the terminal set 11 comprises a first terminal 111 and a second terminal 112, spaced apart; each backlight 40 has a first pin 41 and a second pin 42 on bottom surface, the first pin 41 and the second pin 42 of each backlight 40 are respectively electrically connected to the first terminal 111 and the second terminal 112 of the corresponding terminal set 11.

Moreover, refer to FIG. 3. In the first embodiment of the present invention, each backlight 40 is fixed on the TFT array substrate 10 through an anisotropic conductive film (ACF) 100. The specific fixation method is low-temperature hot pressing, so that the first pin 41 and the second pin 42 of the backlight source 40 are respectively electrically connected to the first terminal 111 and the second terminal 112 of the corresponding terminal set 11 through ACF 100.

Specifically, refer to FIG. 1 and FIG. 3. In the first embodiment of the present invention, the top surface of the TFT array substrate 10 is disposed with a first wire 12 and a second wire 13, spaced apart. Refer to FIG. 3. The first terminal 111 of each terminal set 11 is connected with the first wire 12, and the second terminal 112 of each terminal set 11 is connected with the second wire 13. Refer to FIG. 1. the TFT array substrate 10 further comprises a fourth region 104 connected to the first region 101, the second region 102, and the third region 103. The LCD device further comprises a circuit board 90 bonded through a flexible connection unit 110 on the fourth region 104 of the TFT array substrate 10. The circuit board 90 is the X-board of the LCD device. Both the first wire 12 and the second wire 13 are electrically connected to the circuit board 90. So that the circuit board 90 can use the first wire 12 and the second wire 13 to transmit current to the backlights 40 to drive the backlights 40 to emit light simultaneously. Refer to FIG. 1. In the first embodiment of the present invention, the first wire 12 is located in the first region 101, the third region 103, and the fourth region 104 of the TFT array substrate 10, and the second wire 13 is located in the first region 101, the third region 103, and the fourth region 104 of the TFT array substrate 10. Preferably, in the first embodiment of the present invention, the first wire 12, the second wire 13, the first terminals 111 and the second terminals 112 of the terminal sets 11 are obtained by vaporizing to deposit a metal layer on top of the TFT array substrate 10 and then patterning the metal layer.

It should be noted that in the first embodiment of the present invention, the two backlight sets 40 are disposed at the first region 101 and the third region 103 of the TFT array substrate 10 beyond the CF substrate 20 respectively. Specifically, the backlights 40 are disposed at the top surface of the TFT array substrate 10 and the light-exiting surfaces 41 of the backlights 40 are respectively opposite to the two sides 211 of the base substrate 21 of the CF substrate 20. The CF substrate 20 is made of a light-guiding material, so that the CF substrate 20 functions as a light-guiding plate structure in a known backlight module to guide the light emitted from the light-exiting surfaces 41, the light passes through the LC layer 30 and emits from the TFT array substrate 10 for display. Compared with the prior art, the thickness of the entire LCD device can be greatly reduced, suitable for reducing product cost and improving product quality. Also, by disposing the top surface of the TFT array substrate 10 with the terminal sets 11 corresponding to the backlight sets 40, and the first wire 12 and the second wire 13 respectively electrically connected to the first terminals 111 and second terminals 112 of the terminal sets 11, and electrically connecting the first wire 12 and the second wire 13 to the circuit board 90, the present invention is convenient in driving the backlight sets 40.

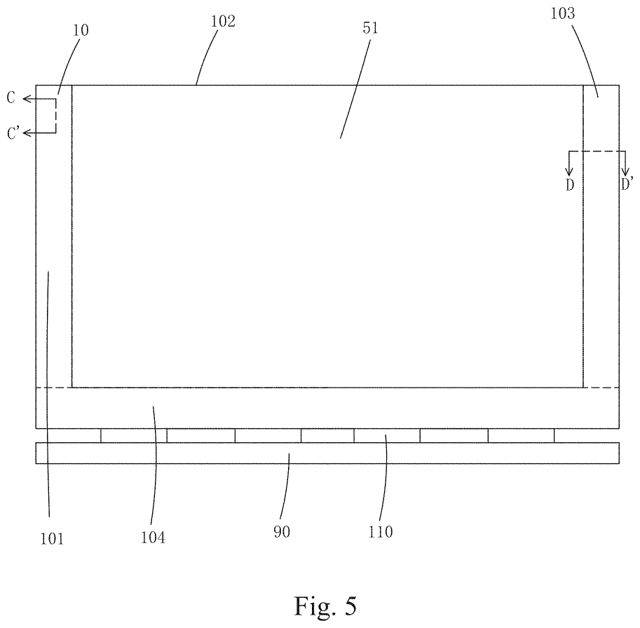

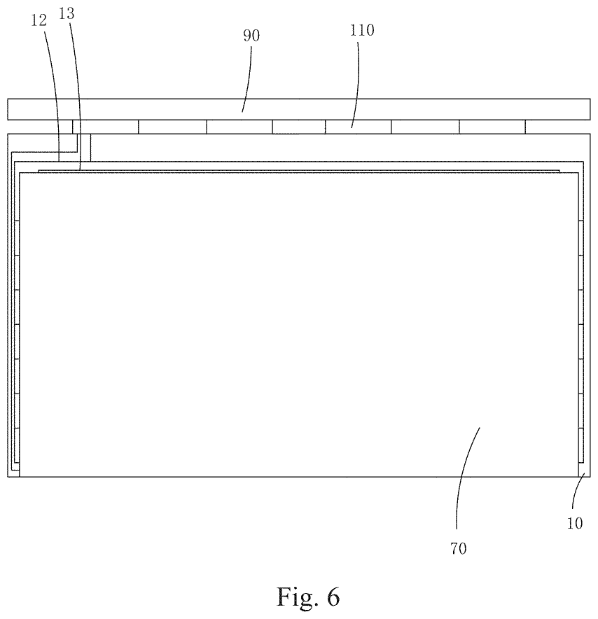

Refer to FIG. 5 to FIG. 8. The second embodiment of the LCD device provided by the present invention differs from the first embodiment in that both the two backlight sets 40 are disposed at bottom surface of the TFT array substrate 10.

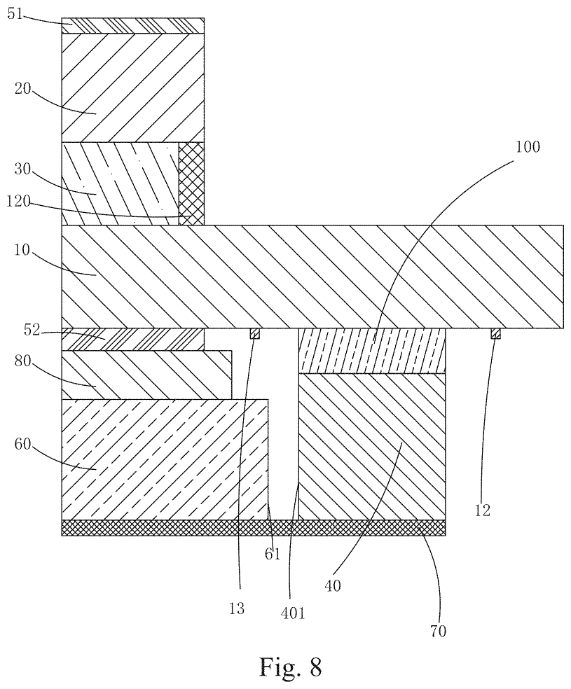

Refer to FIG. 8. The LCD device further comprises a light-guiding plate 60 disposed under the TFT array substrate 10, a reflection sheet 70 disposed on a bottom surface of the light-guiding plate 60, and an optical film set 80 disposed between the TFT array substrate 10 and the light-guiding plate 60. The light-guiding plate 60 has two opposite light incident surfaces 61. The light-exiting surfaces 401 of the backlight set 40 located in the first region 101 are all opposite to one of the two light incident surfaces 61 of the light-guiding plate 60, and the light-exiting surfaces 401 of the backlight set 40 located in the third region 103 are all opposite to the other of the two light incident surfaces 61 of the light-guiding plate 60.

Specifically, refer to FIG. 8. In the second embodiment, the upper polarizer 51 is disposed on top of the CF substrate 20, and the lower polarizer 52 is disposed between the TFT array substrate 10 and the optical film set 80.

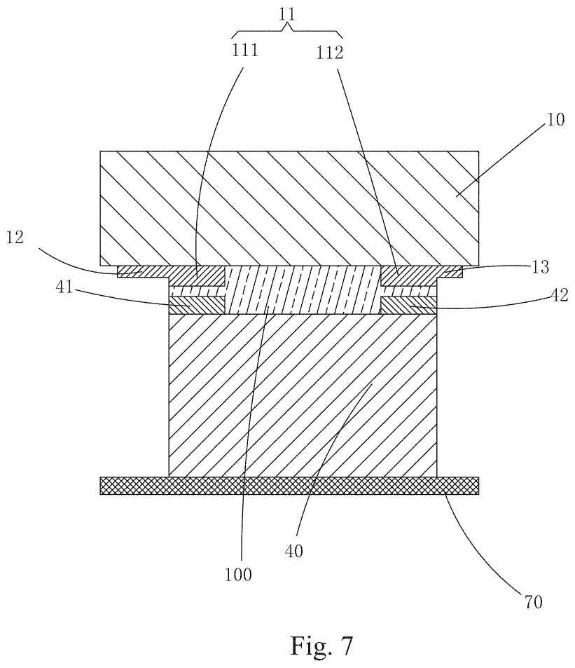

Specifically, as shown in FIG. 7, in the second embodiment of the present invention, the terminal set 11 is disposed at the bottom surface of the TFT array substrate 10; also, the first wire 12 and the second wire 13 are disposed at the bottom surface of the TFT array substrate 10. Preferably, in the second embodiment of the present invention, the first wire 12, the second wire 13, the first terminals 111 and the second terminals 112 of the terminal sets 11 are obtained by vaporizing to deposit a metal layer on the bottom surface of the TFT array substrate 10 and then patterning the metal layer.

The remaining of the second embodiment is the same as the first embodiment, and the detailed description is omitted here.

It should be noted that in the second embodiment of the present invention, the backlights 40 are disposed at the bottom surface of the TFT array substrate 10, and an optical film set 80, a light-guiding plate 60, and a reflection sheet 70 are successively disposed below the TFT array substrate 10. The light-exiting surfaces 401 of the backlights 40 respectively face the two light incident surfaces 61 of the light-guiding plate 60. The light emitted from the backlights 40 enters the light-guiding plate 60 through the light incident surface 61, passes light-guiding plate 60, the TFT array layer 10, the LC layer 30, and is emitted from a side of the CF substrate 20 for display. Compared with the prior art, the thickness of the entire LCD device can be greatly reduced, suitable for reducing product cost and improving product quality. Also, by disposing the bottom surface of the TFT array substrate 10 with the terminal sets 11 corresponding to the backlight sets 40, and the first wire 12 and the second wire 13 respectively electrically connected to the first terminals 111 and second terminals 112 of the terminal sets 11, and electrically connecting the first wire 12 and the second wire 13 to the circuit board 90, the present invention is convenient in driving the backlight sets 40.

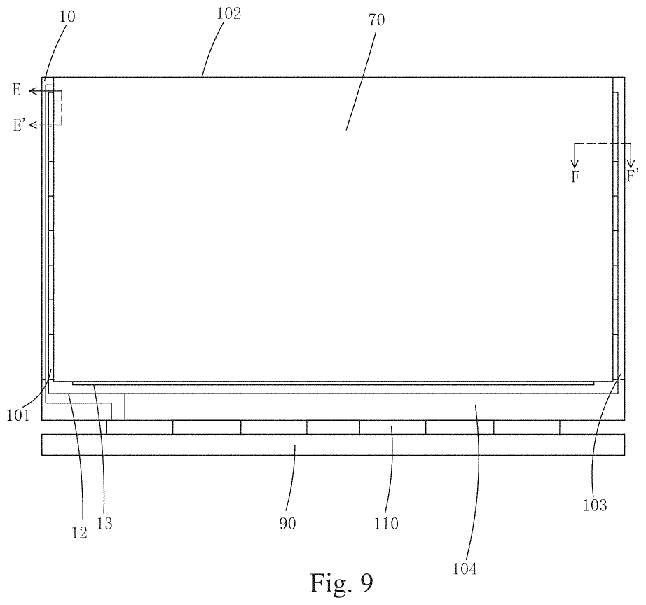

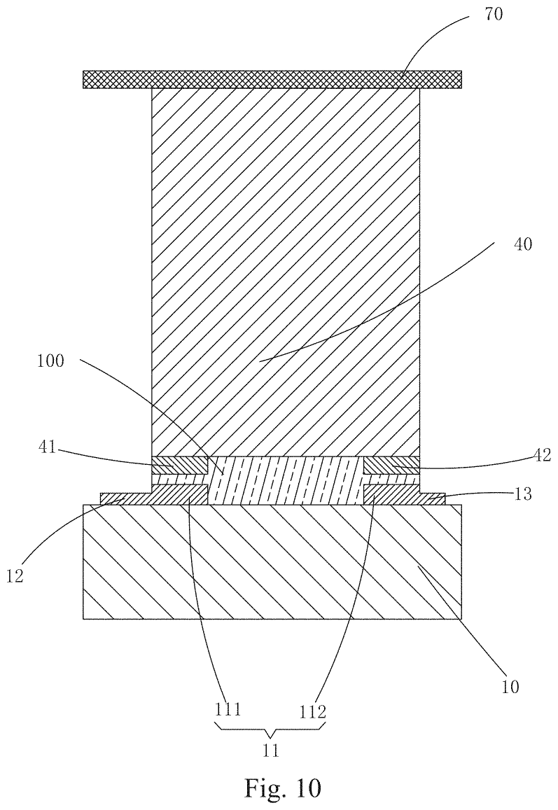

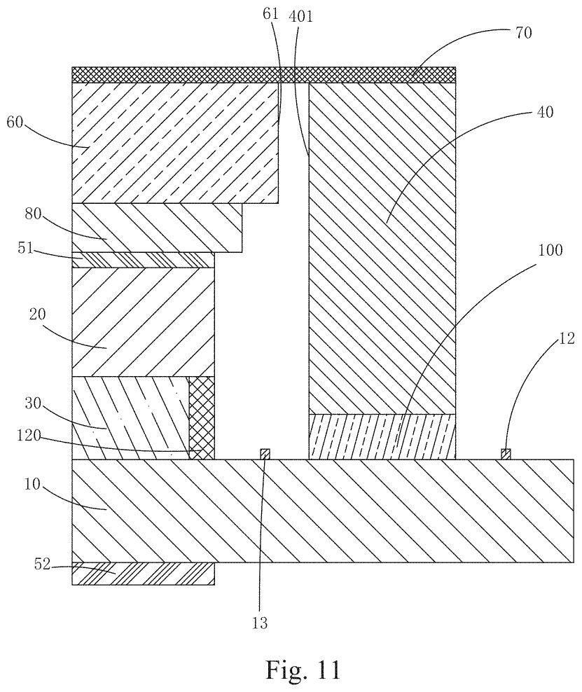

Refer to FIG. 9 to FIG. 11. The third embodiment of the present invention differs from the first embodiment in that the LCD device further comprises a light-guiding plate 60 disposed on top of the CF substrate 20, a reflection sheet 70 disposed on a top surface of the light-guiding plate 60, and an optical film set 80 disposed between the CF substrate 20 and the light-guiding plate 60.

The light-guiding plate 60 has two opposite light incident surfaces 61; the light-exiting surfaces 401 of the backlight set 40 located in the first region 101 are all opposite to one of the two light incident surfaces 61 of the light-guiding plate 60, and the light-exiting surfaces 401 of the backlight set 40 located in the third region 103 are all opposite to the other of the two light incident surfaces 61 of the light-guiding plate 60.

Specifically, in the third embodiment of the present invention, the upper polarizer is disposed between the CF substrate 20 and the optical film set 80.

The remaining of the third embodiment is the same as the first embodiment, and the detailed description is omitted here.

It should be noted that in the third embodiment of the present invention, the backlights 40 are disposed at the top surface of the TFT array substrate 10, and an optical film set 80, a light-guiding plate 60, and a reflection sheet 70 are successively disposed above the CF substrate 10. The light-exiting surfaces 401 of the backlights 40 respectively face the two light incident surfaces 61 of the light-guiding plate 60. The light emitted from the backlights 40 enters the light-guiding plate 60 through the light incident surface 61, passes light-guiding plate 60, the CF substrate 20, the LC layer 30, and is emitted from a side of the TFT array substrate 10 for display. Compared with the prior art, the thickness of the entire LCD device can be greatly reduced, suitable for reducing product cost and improving product quality. Also, by disposing the bottom surface of the TFT array substrate 10 with the terminal sets 11 corresponding to the backlight sets 40, and the first wire 12 and the second wire 13 respectively electrically connected to the first terminals 111 and second terminals 112 of the terminal sets 11, and electrically connecting the first wire 12 and the second wire 13 to the circuit board 90, the present invention is convenient in driving the backlight sets 40.

In summary, the LCD device provided by the present invention integrates the structure of the LCD panel and the backlight module, and directly disposes the backlights of the backlight module on the TFT array substrate of the LCD panel, so that the backlights are disposed on the top surface of the TFT array substrate. The base substrate of the CF substrate is used as a light-guiding plate or a separate light-guiding plate is used to guide the light emitted by the backlights, or the backlights are disposed on the bottom surface of the TFT array substrate and uses a separate the light-guiding plate to guide the light emitted by the backlights. The TFT array substrate is further provided with terminals corresponding to the pins of the backlights and wires connected to the terminals, so that the backlights can be driven by a circuit board connected to the wires to effectively reduce the thickness of the LCD device, reduce product cost and improve product quality.

It should be noted that each of the embodiments in this specification is described in a progressive manner, each of which is primarily described in connection with other embodiments with emphasis on the difference parts, and the same or similar parts may be seen from each other. For the device embodiment, since it is substantially similar to the method embodiment, the description is relatively simple and the relevant description may be described in part of the method embodiment.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A liquid crystal display (LCD) device, comprising: an TFT array substrate, a color filter (CF) substrate disposed on the thin film transistor (TFT) array substrate, a liquid crystal (LC) layer sandwiched between the TFT array substrate and the CF substrate, and two backlight sets disposed on the TFT array substrate; both the two backlight sets being disposed at top surface of the TFT array substrate or bottom surface of the TFT array substrate;
the TFT array substrate being disposed with a first region, a second region, and a third region successively, wherein the second region corresponds to the CF substrate; one of two backlight sets is disposed in the first region, and the other set is disposed in the third region; and each backlight of the backlight set has a light-exiting surface, the light-exiting surface of each backlight being located on a side near the second region.

2. The LCD device as claimed in claim 1, wherein the two backlight sets are disposed at the top surface of the TFT array substrate;
the CF substrate comprises a base substrate having two sides respectively corresponding to boundary between the first region and the second region and boundary between the second region and the third region; the light-exiting surfaces of the backlight set located in the first region are all opposite to the side of the base substrate corresponding to the boundary between the first region and the second region, and the light-exiting surfaces of the backlight set located in the third region are all opposite to the side of the base substrate corresponding to the boundary between the second region and the third region;
the base substrate is made of a light-conductive material.

3. The LCD device as claimed in claim 2, wherein the LCD device further comprises an upper polarizer disposed between the CF substrate and the LC layer, and a lower polarizer disposed on a bottom surface of the TFT array substrate.

4. The LCD device as claimed in claim 1, wherein the two backlight sets are disposed at the top surface of the TFT array substrate;
the LCD device further comprises a light-guiding plate disposed under the TFT array substrate, a reflection sheet disposed on a bottom surface of the light-guiding plate, and an optical film set disposed between the TFT array substrate and the light-guiding plate;
the light-guiding plate has two opposite light incident surfaces; the light-exiting surfaces of the backlight set located in the first region are all opposite to one of the two light incident surfaces of the light-guiding plate, and the light-exiting surfaces of the backlight set located in the third region are all opposite to the other of the two light incident surfaces of the light-guiding plate.

5. The LCD device as claimed in claim 4, wherein the LCD device further comprises an upper polarizer disposed on a top surface of the CF substrate, and a lower polarizer disposed between the TFT array substrate and the optical film set.

6. The LCD device as claimed in claim 1, wherein the two backlight sets are disposed at the top surface of the TFT array substrate;
the LCD device further comprises a light-guiding plate disposed on top of the CF substrate, a reflection sheet disposed on a top surface of the light-guiding plate, and an optical film set disposed between the CF substrate and the light-guiding plate;
the light-guiding plate has two opposite light incident surfaces; the light-exiting surfaces of the backlight set located in the first region are all opposite to one of the two light incident surfaces of the light-guiding plate, and the light-exiting surfaces of the backlight set located in the third region are all opposite to the other of the two light incident surfaces of the light-guiding plate.

7. The LCD device as claimed in claim 6, wherein the LCD device further comprises an upper polarizer disposed between the CF substrate and the optical film set, and a lower polarizer disposed at the bottom surface of the TFT array substrate.

8. The LCD device as claimed in claim 1, wherein the backlight set located in the first region is arranged in a row in an arrangement parallel to the boundary between the first region and the second region;
the backlight set located in the third region is arranged in a row in an arrangement parallel to the boundary between the second region and the third region;
each backlight of the backlight set an OLED light source.

9. The LCD device as claimed in claim 1, wherein one of the top surface and the bottom surface of the TFT array substrate disposed with the backlight sets is disposed with a terminal set corresponding to each backlight set respectively; the terminal set comprises a first terminal and a second terminal, spaced apart; each backlight has a first pin and a second pin on bottom surface, the first pin and the second pin of each backlight are respectively electrically connected to the first terminal and the second terminal of the corresponding terminal set;
one of the top surface and the bottom surface of the TFT array substrate disposed with the backlight sets is disposed with a first wire and a second wire, spaced apart, the first terminal of each terminal set is connected with the first wire, and the second terminal of each terminal set is connected with the second wire;
the TFT array substrate further comprises a fourth region connected to the first region, the second region, and the third region; the LCD device further comprises a circuit board bonded on the fourth region of the TFT array substrate, and both the first wire and the second wire are electrically connected to the circuit board.

10. The LCD device as claimed in claim 9, wherein each backlight is fixed on the TFT array substrate through an anisotropic conductive film, so that the first pin and the second pin of the backlight are respectively electrically connected to the first terminal and the second terminal of the corresponding terminal set.
